(19) United States
(12) Patent Application Publication
(10) Pub. No.: US 2007/0034252 A1
(43) Pub. Date: Feb. 15, 2007

(54) Covertible pad support for receiving at least two pads of different dimensions

(75) Inventor: Yvon Pellegrin, Montpellier (FR)

Correspondence Address: EGBERT LAW OFFICES, 412 MAIN STREET, 7TH FLOOR, HOUSTON, TX, 77002, US

(73) Assignee: SEMCO ENGINEERING SA, Montpellier Cedex 5 (FR)

(21) Appl. No.: 10/570,450

(22) PCT Filed: Jul. 27, 2004
(86) PCT No.: PCT/EP04/51612

§ 371 Date: Jul. 12, 2006

(30) Foreign Application Priority Data
Jul. 28, 2003 (FR) 0309253

(51) Int. Cl. H01L 31/00

(52) U.S. Cl. 136/256

(57) ABSTRACT

The convertible pad support can receive at least two different types of pads of different dimensions. The support includes a three-dimensional structure defining a storage volume wherein the pads are disposed. The structure includes two lateral flanks which are firmly connected by two fixed arms and receives at least one additional arm which can be placed opposite the storage volume. The structure maintains the pads inside the storage volume with the aid of the other arms whereby the normal distance between the additional arm and the geometric longitudinal axis of one of the fixed arms can be adjusted in order to adapt support to the dimensions of the pads to be received.

### RELATED U.S. APPLICATIONS

Not applicable.

### STATEMENT REGARDING FEDERALL SPONSORED RESEARDCH OR DEVELOPMENT

Not applicable.

### REFERENCE TO MICROFICHE APPENDIX

Not applicable.

### FIELD OF THE INVENTION

This invention concerns a 45° silicon pad support to hold several silicon pads at a constant spacing from one another, said support being convertible so as to receive silicon pads of different sizes.

### BACKGROUND OF THE INVENTION

The known pad supports comprise several elongated parallel arms rigidly attached through their ends to two side flanks extending perpendicular to the longitudinal axis of each arm. The arms are provided with notches at regular intervals. The pads are slid and housed through their periphery into said notches. Typically, such supports are equipped with four or five arms.

The supports, as described, are designed to receive only one size of pads so that the manufacturers are forced to keep a large stock of supports to meet their clients′ expectations.

For example, square solar cells are available in two dimensions, i.e., 125 mm and 150 mm. Manufacturers must be equipped with supports suitable for the 125 mm pads and with supports suitable for the 150 mm pads.

### BRIEF SUMMARY OF THE INVENTION

This invention concerns a pad support that through simple manipulation can be made suitable to receiving either pads of a first size or pads of a second size.

To that effect, the convertible pad support that can receive at least two pads of different dimensions, consisting of a three-dimensional structure defining a storage volume in which the pads are positioned, said volume having a longitudinal central geometric axis AA′ contained in a longitudinal median geometric plane P of said structure. The structure comprises two lateral flanks perpendicular to the central geometrical axis, and at least two fixed arms parallel to said central geometrical axis, rigidly attached to the two lateral flanks and provided with notches turned toward the storage volume. The different notches are arranged in successive geometrical planes, parallel at a constant spacing from one another, and perpendicular to the longitudinal central axis of the storage volume. The pad support is characterized mainly by at least one additional arm parallel to the geometrical axis of the storage volume and equipped with notches turned toward said storage volume, said additional arm co-operating in a fixing action with the three-dimensional structure and being designed to be positioned facing the storage volume and to ensure, in combination with the other arms, the holding of the pads in the storage volume, the normal distance between this additional arm and the longitudinal geometrical axis of any fixed arm being adjustable so as to adapt said support to the dimensions of the pads to be received.

Thus, one single support can receive lots of pads of different dimensions, which reduces significantly the number of supports that manufacturers must have to meet the various requirements.

According to another characteristic of the invention, the position-adjustable arm is attached in a removable manner to the structure. One of the two elements, either structure or additional arm, comprises at least two first pairs of fixing components, the components of each first pair being apart from one another and aligned according to a fixing geometrical axis, parallel to the longitudinal central geometrical axis of the storage volume. The normal distance between the fixing geometrical axis of each pair of fixing components and the longitudinal geometrical axis of any fixed arm is different from one pair of fixing components to the next. The other element, either structure or additional arm, comprises at least a second pair of fixing components apart from each other and aligned according to another fixing geometrical axis parallel to the longitudinal central geometrical axis of the storage volume. The fixing components of said second pair are the conjugates of the fixing components of the first two pairs and said second pair of fixing components being designed to co-operate in a fixing action with either one of the first two pairs of fixing components so as to adapt said support to the dimensions of the pads to be received.

Because of this characteristic, adaptation of the support under the invention can be done in a simple and quick manner.

According to another characteristic of the invention, the additional arm is attached to the structure in a swiveling manner, with an angular push-out/pull-in action in relation to the longitudinal median geometrical plane of said structure, said arms through angular swiveling toward the median plane being turned in toward the storage volume.

The additional arm, through swiveling, can be positioned laterally to the storage volume and leave free passage for a lot of pads that can thus be inserted into or removed from the support through a movement according to an axis perpendicular to the longitudinal axis of the storage volume and contained in the median geometrical plane of this volume. Thus, the means to insert or remove the lot of pads into or from the support will be simpler, knowing that the insertion or removal for the current supports is done in an oblique direction in relation to the median plane, which leads to having more complex means of insertion and removal.

According to another characteristic of the invention, the fixed arms of the structure are recessed in the lateral flanks of the latter. A recess link ensures proper rigidity, which makes it possible to use arms of relatively great lengths and to produce higher capacity supports.

According to a characteristic form of the invention, the support comprises on one hand a structure that has four fixed arms arranged according to the longitudinal axes of an isosceles trapeze type rectangular prism and on the other hand a movable and/or removable additional arm.

### BRIEF DESCRIPTION OF THE SEVERAL VIEWS OF THE DRAWINGS

Other advantages and characteristics of the invention will become apparent when reading the description of a preferred embodiment given as an indicative example only, with reference to the attached drawings.

FIG. 1 is a perspective view of a support under the invention, configured to receive pads of a first dimensional class, the additional arm being in a turned-in position.

FIG. 2 is a perspective view of the support according to FIG. 1, the additional arm being in a moved-apart position.

FIG. 3 is a perspective view of a support under the invention, configured to receive pads of a second dimensional class, the additional arm being in a turned-in position.

FIG. 4 is a perspective view of the support according to FIG. 3, the additional arm being in a moved-apart position.

FIGS. 5 through 7 are detailed sectional views of the support under the invention.

### DETAILED DESCRIPTION OF THE INVENTION

As shown, the convertible support under the invention can receive two types of square silicon pads 2 with different dimensions for the pad sides. After proper treatment, these pads 2 can be used to make, for example, photovoltaic, or other cells.

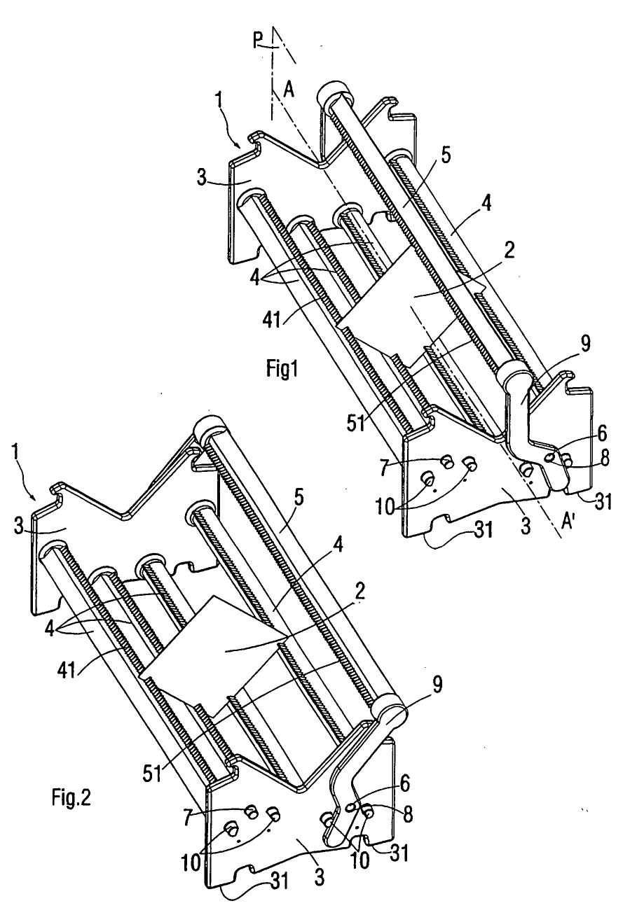

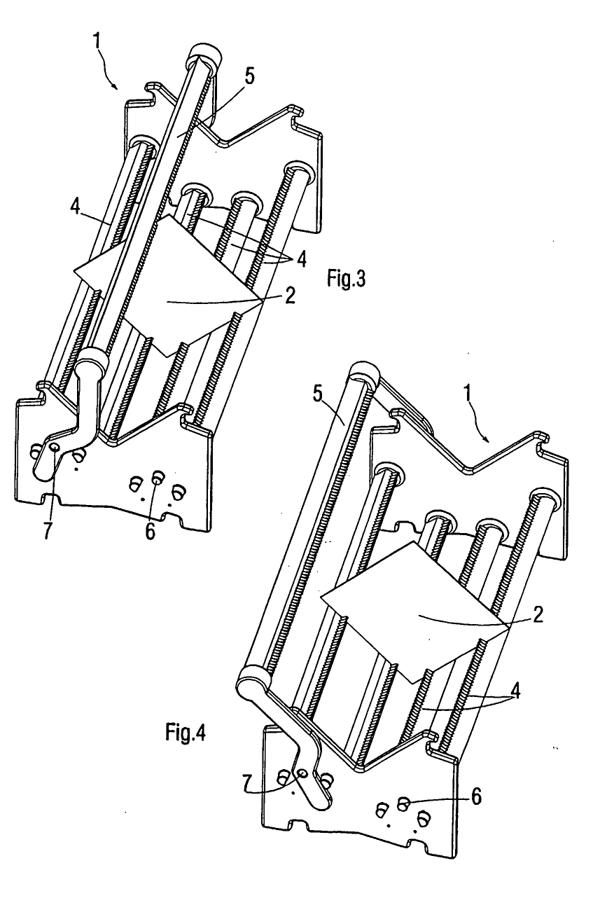

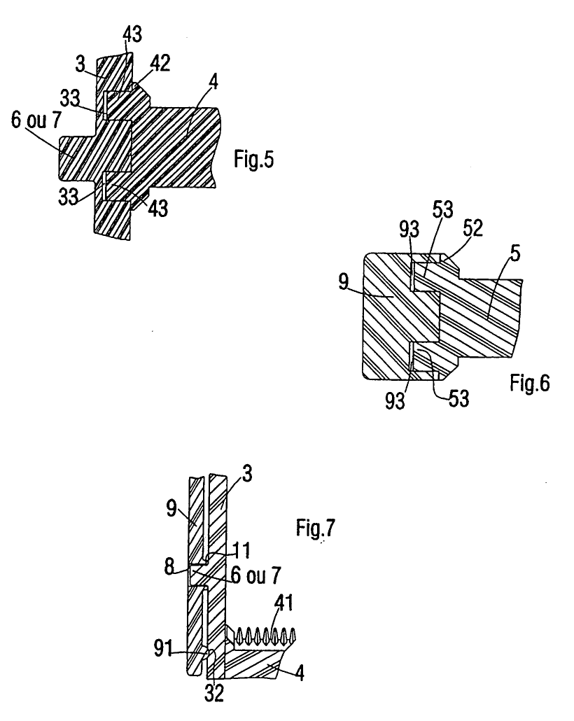

In FIGS. 1 through 4, only one pad 2 is represented for reasons of drawing simplification and legibility. It is well understood that the support is designed to receive a lot of several pads.

The convertible support consists of a three-dimensional structure 1 defining a storage volume in which the pads 2 are positioned, said volume having a longitudinal central geometrical axis AA′ contained in a longitudinal median geometrical plane P of said structure.

The structure 1 comprises two lateral flanks 3 perpendicular to the central geometrical axis AA′, and four fixed arms 4, parallel said central geometrical axis, attached rigidly to the two lateral flanks 3 and provided with notches 41 turned toward the storage volume, and arranged according to successive geometrical planes, parallel, at a constant spacing from one another, and perpendicular to the longitudinal central axis AA′ of the storage volume.

According to the invention, the convertible support is equipped with at least one additional arm 5 parallel to the geometrical axis of the storage volume and equipped with notches 51 turned toward said storage volume. This additional arm 5 co-operates in a fixing action with the three-dimensional structure 1 and is designed to be positioned facing the storage volume to ensure, in combination with the other arms, the holding of the pads 2 in the storage volume. The normal distance between this additional arm 5 and the geometrical axis of any fixed arm is adjustable so as to adapt the support to the dimensions of the pads 2 to be received. The position of the additional arm 5 is adjustable.

The four fixed arms 4, are arranged according to the longitudinal axes of an isosceles trapeze type rectangular prism, the longitudinal median plane of the storage volume forming the plane of symmetry of this prism. The bases of this prism are made by the two lateral flanks 3.

The structure 1, perpendicular to the plane of symmetry P as defined, has two coplanar, plane supporting and positioning faces 31, formed respectively on the two lateral flanks 3. These supporting and positioning faces 31 are in fact made by the lower edges of the two lateral flanks 3.

The face of the rectangular prism corresponding to the small base of the isosceles trapeze formed by the cross section is turned downward.

The four fixed arms fixes 4 actually form a cradle in which the pads 2 are positioned. Each pad 2 rests on the four arms through two adjoining sides and the additional arm 5 comes to rest against one of the two other sides of the pad. This five-arm arrangement allows for the vertical positioning of the convertible support. Under that position, the pads are horizontal. The support ensures positioning of the pads at 45°.

Through the two supporting faces 31, the support can be positioned on pad loading and unloading horizontal platforms that transfer machines are generally equipped with.

The four fixed arms 4 of the three-dimensional structure are recess-mounted into the lateral flanks 3. According to a preferred embodiment, each fixed arm 4 has at each end a plate 42, provided with several protruding cylindrical pins 43. For example, four protruding pins, evenly spaced in a circle, are provided.

The protruding pins 43 for the various fixed arms 4 are designed to be set into the blind holes 33 made in the lateral flanks 3 of the structure 1.

The pins 43 in the respective holes will be attached using ultrasonic welding or bonding or other means and techniques. In addition, each plate 42 has a supporting face against the respective lateral flank face internal to the storage volume. This characteristic, in combination with the pin recess-setting ensures excellent bending rigidity of the link of the arms 4 to the respective flank 3, making it possible to provide for arms 4 of greater lengths without any risk of deformation of the structure 1. A structure I with longer arms gives a greater capacity to the support.

The arm 5 with adjustable positions is attached in a removable manner to the structure 1 and, one of the two elements, structure 1 or additional arm 5, comprises at least two first pairs of fixing components 6,7, the components 6,7 of each first pair being apart from each other and aligned according to a fixing geometrical axis, parallel to the longitudinal central geometrical axis AA′ of the storage volume.

The normal distance between the fixing geometrical axis of each pair of fixing components 6,7 and the longitudinal geometrical axis of any fixed arm 4 is different from one pair of fixing components to the next. In another manner, the normal distance between the fixing geometrical axis and the plane supporting faces 31 is different from one pair to the next.

The other element, additional arm 5 or structure 1, comprises at least a second pair of fixing components 8, apart from each other and aligned according to another fixing geometrical axis parallel to the longitudinal central geometrical axis AA′ of the storage volume, the fixing components 8 of said second pair being the conjugates of the fixing components 6,7 of the two first pairs and said second pair of fixing components being designed to cooperate in a fixing action with either one of the first two pairs of fixing components 6,7 so as to adapt the support 1 to the dimensions of the pads 2 to be received.

According to the preferred embodiment, the first two pairs of fixing components 6,7 are provided on the lateral flanks 3 of the structure 1, each lateral flank comprising one of the fixing components of the two first pairs of fixing components, and the additional arm 5, perpendicular to its longitudinal axis, comprises two lateral lugs 9, subject to elastic deformation, bearing at a distance from said arm 5, the fixing components 8 of the second pair of fixing components.

The lateral lugs will be recess-mounted at the ends of the additional arm 5. To that effect, the additional arm 5, just like the fixed arms 4, has at each end a plate 52 provided with several protruding cylindrical pins 53 designed to be inserted into the blind holes 93 made in the respective elastic lug.

The pins 53 will be set in the holes 93 using ultrasonic welding, bonding or other means and techniques.

In addition, each plate 52 has a supporting face against the respective flexible lug. This characteristic, in combination with the set pins 53 ensures excellent bending rigidity of the link of the arm 5 to the flexible lugs 9.

The first two pairs of fixing components 6,7 are provided on the large faces external to the storage volume of the two lateral flanks 3 and the lateral lugs 9 of the additional arm 5 face these two large faces. According to a preferred embodiment, each fixing component 6,7 of the first two pairs of fixing components 6,7 consists of a boss and the fixing component 8 with which each lateral lug 9 is provided to socket-fit with the respective boss.

The adaptation of the support to a given size of pads to be processed is done by changing the position of the additional arm 5, the latter being released from the cooperating pair of fixing components 6 or 7 to be engaged onto the other pair.

As one can see, the operation is relatively simple, easy and quick to be carried out as all one has to do is first to move apart the elastic lugs 9 and to release the fixing components 8 of components 6 or 7 of the co-operating pair, and then to engage these fixing components 8 onto the fixing components 7 or 6 of the other first pair of fixing components.

According to the preferred embodiment, with regard to the longitudinal median plane AA′, the fixing components 7 are on one side of this plane while the other fixing components 6 are on the other side. For that reason, when changing position, the arm 5 will pivot on itself so that the notches 51 provided are always positioned facing the storage volume.

Preferably, the additional arm 5 is attached to the structure 1 in a swiveling manner, with an angular push-out/pull-in action in relation to the longitudinal median geometrical plane. The additional arm can thus be pulled in toward the storage volume in order to hold in the latter the lot of pads located therein or be laterally moved aside from this volume to allow for either the removal of the lot of pads, or the insertion of a new lot in a direction perpendicular to the supporting faces 3 1. To implement such characteristics, the fixing components 6 and 7 will be cylindrical and form trunnions and the fixing components 8 will take the form of a cylindrical bore.

The amplitude of the swiveling movement of the additional arm is limited by the thrusts 10 attached to the structure. More specifically, said thrusts consist of bosses protruding on the faces of two lateral flanks 3 external to the storage volume. Preferably, two thrusts 10 are associated with each component 6 or 7.

According to a preferred embodiment, each lateral lug 9 of the additional arm 5 comprises two parallel, straight sections, laterally offset in relation to one another other and joined together through a form of elbow, the straight section being rooted into the arm 5, offset toward the longitudinal median plane of the structure.

This arrangement is conducive to facilitating the turning-in movement of the arm 5 onto the storage volume.

Preferably, the retraction and release positions of the additional arm 5 are indexed. To that effect, each lateral lug 9 of the additional arm comprises on the one of its two faces that faces the lateral flank 3, a protruding boss 91 in the shape of a spherical cap and each lateral flank is provided with impressions in the shape of a spherical cap 32, designed to receive the boss.

Preferably, each lateral lug 9 of the additional arm 5 rests against the respective lateral flank 3 through an elongated boss 11 ensuring linear contact. This elongated boss 11 can develop along an arc of circle circumference. The purpose of this arrangement that is designed to keep the two elastic lugs 9 away from the lateral flanks 3 is to facilitate the flow of the flushing liquids and to prevent any accumulation of the latter between two surfaces in contact, thus reducing the risk of pollution of the treatment bath with these flushing or washing liquids.

It is understood that this invention can accommodate any features and alternative options from the field of technical equivalents without going outside the scope of the patent.

I claim:

1. Convertible pad support receiving at least two types of pads of different dimensions, said convertible pad support comprising:
a three-dimensional structure defining a storage volume, the pads being positioned in said storage volume, said storage volume having a longitudinal central geometric axis contained in a longitudinal median geometric plane said structure, said structure comprises:
two lateral flanks perpendicular to the central geometrical axis, and
at least two fixed arms parallel to the central geometrical axis, the fixed arms being rigidly attached to the two lateral flanks and provided with notches turned toward the storage volume, different notches being arranged in successive geometrical planes, parallel at a constant spacing from one another, and perpendicular to the longitudinal central axis of the storage volume; wherein at least one additional arm is parallel to the geometrical axis of the storage volume and equipped with notches turned toward said storage volume, said additional arm co-operating in a fixing action with the three-dimensional structure and being able to be positioned facing the storage volume and to ensure, in combination with the other arms, holding of the pads in the storage volume, a normal distance between the additional arm and the longitudinal geometrical axis of any fixed arm being adjustable so as to adapt support to dimensions of the pads to be received.

2. Convertible support, according to claim 1, wherein the additional arm is attached in a removable manner to the structure; and
wherein one of either said structure or the additional arm, comprises at least two first pairs of fixing components, the fixing components of each first pair being apart from one another and aligned according to a fixing geometrical axis, parallel to the longitudinal central geometrical axis of the storage volume, the normal distance between the fixing geometrical axis of each pair of fixing components and the longitudinal geometrical axis of any fixed arm being different from one pair of fixing components to the next; and
wherein the other one of either said structure or the additional arm, comprises at least a second pair of fixing components apart from each other and aligned according to another fixing geometrical axis parallel to the longitudinal central geometrical axis of the storage volume, the fixing components of said second pair being conjugates of the fixing components of the first two pairs, said second pair of fixing components being able to co-operate in a fixing action with either one of the first two pairs of fixing components so as to adapt support to dimensions of the pads to be received.

3. Convertible support according to claim 2, wherein the first two pairs of fixing components are provided on the lateral flanks, each lateral flank comprising one of the fixing components of the two first pairs of fixing components; and
wherein the additional arm, perpendicular to its longitudinal axis, comprises two lateral lugs, subject to elastic deformation, bearing, at a distance from the additional arm, the fixing components of the second pair of fixing components.

4. Convertible support according to claim 3, wherein the first two pairs of fixing components are provided on faces external to the storage volume of the two lateral flanks; and
wherein said lateral lugs of the additional arm face said faces external to the storage volume.

5. Convertible support according to claim 3, wherein each fixing component of the first two pairs of fixing components is comprised of a boss; and
wherein the fixing component with which each lateral lug is equipped is comprised of a bore to socket-fit with a respective boss.

6. Convertible support according to claim 3, wherein the additional arm is attached to the structure in a swiveling manner, with an angular push-out/pull-in action in relation to the longitudinal median geometrical plane of said structure, the additional arm through angular swiveling toward the median plane being turned in toward the storage volume.

7. Convertible support according to claim 6, wherein amplitude of the swiveling movement of the additional arm is limited by thrusts attached to the structure.

8. Convertible support according to claim 3, wherein said lateral lugs of the additional arm comprises two parallel, straight sections, laterally offset in relation to one another other and joined together through a form of elbow, the straight section being rooted into the additional arm, offset toward the longitudinal median plane of the structure.

9. Convertible support according to claim 3, wherein each lateral lug of the additional arm rests against a respective lateral flank through an elongated boss ensuring linear contact.

10. Convertible support according to claim 1, wherein the fixed arms of the structure are recess-mounted in the lateral flanks thereof.

11. Convertible support according to claim 1, wherein said structure has four fixed arms arranged according to the longitudinal axes of an isosceles trapeze type rectangular prism and an additional arm.
